(19) United States
(12) Patent Application Publication
(10) Pub. No.: US 2014/0286470 A1
(43) Pub. Date: Sep. 25, 2014

(54) PHASE LOCKED LOOP AND CLOCK AND DATA RECOVERY CIRCUIT

(71) Applicant: Sony Corporation, Tokyo (JP)

(72) Inventors: Zhiwei Zhou, Tokyo (JP); Takashi Masuda, Tokyo (JP); Tetsuya Fujiwara, Kanagawa (JP)

(73) Assignee: Sony Corporation, Tokyo (JP)

(21) Appl. No.: 14/208,077

(22) Filed: Mar. 13, 2014

(30) Foreign Application Priority Data
Mar. 21, 2013 (JP) 2013-058320

(51) Int. Cl. H03L 7/099; H03L 7/093

(52) U.S. Cl. CPC H03L 7/0993; H03L 7/093
USPC 375/376; 327/159

(57) ABSTRACT

A clock and data recovery circuit includes: a first current source configured to supply a charge current through a first signal line; a second current source configured to supply a discharge current through a second signal line; a loop filter configured to convert the charge current into a first voltage signal and output the first voltage signal through a third signal line, and to convert the discharge current into a second voltage signal and output the second voltage signal through a fourth signal line; a voltage control oscillator configured to be controlled in frequency; and a phase detector configured to receive a data signal from outside and receive a clock signal from the voltage control oscillator, and to supply a control signal to each of the first current source and the second current source, and generate a recovery clock signal and a recovery data signal.

### CROSS-REFERENCE TO RELATED APPLICATIONS

This application claims the benefit of Japanese Priority Patent Application JP 2013-058320 filed Mar. 21, 2013, the entire contents of which are incorporated herein by reference.

### BACKGROUND

The present disclosure relates to a phase locked loop and a clock and data recovery circuit.

Recently, in a field of an information device, a full-high-definition television, and the like, large-volume digital data is necessary to be transmitted at high speed and at low cost. Hence, fast serial transmission is widely used. A receiver for fast serial transmission reproduces a clock in synchronization with a predeterminately encoded, received data array and reproduces data with a clock and data recovery circuit (hereinafter, abbreviated as “CDR”) using a technique of a phase locked loop.

It is to be noted that Japanese Unexamined Patent Application Publication No. 2010-35098 (JP-A-2010-35098)) discloses a technology that is considered to be similar to the technology of the present disclosure. JP-A-2010-35098 discloses the subject matter of a phase locked loop in which the natural frequency ωn and a damping factor ζ are each freely variable and are each allowed to be calibrated.

FIG. 25 is a block diagram of a phase locked loop 2501 in the related art.

A phase/frequency detector 102 compares each of a frequency and a phase of a reference clock to each of those of a feedback clock, and outputs an UP signal and a DN signal each being a PWM control signal based on results of the comparison. A charge pump 2502 outputs a current based on the UP signal and the DN signal. Specifically, the charge pump 2502 converts the digital signals into a current signal. A loop filter 2503 removes an unnecessary high-frequency component from the current signal, i.e., the output signal of the charge pump 2502, and converts the current signal into a voltage signal. The voltage signal is to control a voltage control oscillator 2504. The voltage control oscillator 2504 outputs a VCO clock that is controlled in oscillation frequency based on the received voltage signal. The VCO clock is divided in frequency into a predetermined frequency by a frequency divider 110, and is then sent to the phase/frequency detector 102.

FIG. 26 is a block diagram of CDR 2601 in the related art.

Operation of the CDR 2601 is similar to that of the phase locked loop 2501.

First, a lock detector 202 compares each of a frequency and a phase of an input data signal to each of those of a first feedback clock to determine whether each of a frequency difference and a phase difference is within a lock range of a phase detector. When the difference is not within the lock range, multiplexers 203a and 203b are selected to be on a phase/frequency detector 204 side. When the difference is within the lock range, multiplexers 203a and 203b are selected to be on a phase detector 205 side.

The phase/frequency detector 204 compares each of a frequency and a phase of an input data signal to each of those of the first feedback clock, and outputs an UP signal and a DN signal each being a PWM control signal based on results of the comparison. The charge pump 2502 outputs a current based on the UP signal and the DN signal received via the multiplexers 203a and 203b. Specifically, the charge pump 2502 converts such digital signals into a current signal. The loop filter 2503 removes an unnecessary high-frequency component from the current signal, i.e., the output signal of the charge pump 2502, and converts the current signal into a voltage signal. The voltage signal is to control the voltage control oscillator 2504. The voltage control oscillator 2504 outputs a second feedback clock (VCO clock) that is controlled in oscillation frequency based on the received voltage signal. The second feedback clock is received by the phase detector 205, and is divided in frequency into a predetermined frequency by the frequency divider 110, and is then sent to the phase/frequency detector 204.

As with the phase/frequency detector 204, the phase detector 205 compares each of a frequency and a phase of the input data signal to each of those of the second feedback clock, and outputs an UP signal and a DN signal each being a PWM control signal based on results of the comparison. The UP signal and the DN signal each being a digital signal are received by the multiplexers 203a and 203b, respectively. Signal processing of the multiplexers 203a and 203b or in later stages is similar to signal processing of the phase/frequency detector 204. The phase detector 205 outputs a recovery clock having a frequency equal to that of the second feedback clock, and recovery data having a phase in synchronization with a phase of the recovery clock. While a lock detection signal output by the lock detector 202 controls the multiplexer 203 to be on the phase detector side, the recovery clock and the recovery data are processed by a subsequent circuit, thereby original data is allowed to be extracted from the input data signal.

### SUMMARY

During an attempt of achieving a high-speed CDR, the inventors have found that stationary phase error due to the charge pump 2502 occurs in each of the phase locked loop 2501 illustrated in FIG. 25 and the CDR 2601 illustrated in FIG. 26 in the related art.

FIGS. 27A and 27B are waveform diagrams explaining stationary phase error in a phase locked loop and in CDR, respectively.

FIG. 27A is a waveform diagram explaining stationary phase error in the phase locked loop. When a reference clock is compared to a feedback clock, a phase shift occurs despite a completely synchronized stationary state. Such a phase shift corresponds to the stationary phase error.

FIG. 27B is a waveform diagram explaining stationary phase error in the CDR. When a recovery clock is compared to recovery data, an edge of the recovery clock, which should be originally located at the data center of the recovery data, is shifted in phase from the data center despite a completely synchronized stationary state. Such a phase shift corresponds to the stationary phase error.

A first cause of the stationary phase error is mismatch between currents output from the two current sources as an entity of the charge pump. There are several causes for the mismatch. Mainly, the mismatch is caused by a shoot-through current generated at timing where the two current sources are simultaneously turned on.

Each of the UP signal and the DN signal that are to control the current sources is a PWM signal, and has a waveform of which the rising and falling are each shown to be duller with an increase in frequency. Specifically, as an operation frequency increases, mismatch caused by a slight shoot-through current, which occurs at a time point where a switching signal is changed, becomes more nonnegligible.

A second cause of the stationary phase error is that the switching signal itself affects a charge current and a discharge current via parasitic capacitances, which are included in MOSFETs as an entity of the two current sources, at a time point where the switching signal is changed. This phenomenon is known as clock feed-through.

It is desirable to provide a phase locked loop and a clock and data recovery circuit that are reduced in stationary phase error.

To solve the above-described issue, according to an embodiment of the present disclosure, there is provided a clock and data recovery circuit, including: a first current source configured to supply a charge current through a first signal line; a second current source configured to supply a discharge current through a second signal line provided separately from the first signal line; a loop filter configured to convert the charge current into a first voltage signal and output the first voltage signal through a third signal line, and to convert the discharge current into a second voltage signal and output the second voltage signal through a fourth signal line; a voltage control oscillator configured to receive the first voltage signal and the second voltage signal so as to be controlled in frequency; and a phase detector configured to receive a data signal from outside and receive a clock signal from the voltage control oscillator, and to supply a control signal to each of the first current source and the second current source, and generate a recovery clock signal and a recovery data signal.

Moreover, to solve the above-described issue, according to an embodiment of the present disclosure, there is provided a phase locked loop, including: a first current source configured to supply a charge current through a first signal line; a second current source configured to supply a discharge current through a second signal line provided separately from the first signal line; a loop filter configured to convert the charge current into a first voltage signal and output the first voltage signal through a third signal line, and to convert the discharge current into a second voltage signal and output the second voltage signal through a fourth signal line; a voltage control oscillator configured to receive the first voltage signal and the second voltage signal so as to be controlled in frequency; and a phase/frequency detector configured to receive a reference signal from outside and receive an oscillation signal from the voltage control oscillator, and to supply a control signal to each of the first current source and the second current source.

According to any of the above-described embodiments of the present disclosure, a phase locked loop and a clock and data recovery circuit that are reduced in stationary phase error are provided.

Other issues, configurations, and effects are clarified by the description of the following embodiments.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a block diagram of a phase locked loop according to an example embodiment of the present disclosure.

FIG. 2 is a block diagram of CDR according to an example embodiment of the present disclosure.

FIGS. 3A and 3B are schematic diagrams illustrating a difference between a charge pump in the related art and a charge pump as an example embodiment of the present disclosure.

FIG. 4 is a circuit diagram of a charge pump and a loop filter according to a first example of the related art.

FIG. 5 is a circuit diagram of a charge pump and a loop filter according to a first embodiment of the present disclosure.

FIG. 6 is a circuit diagram of a charge pump and a loop filter according to a second example of the related art.

FIG. 7 is a circuit diagram of a charge pump and a loop filter according to a second embodiment of the present disclosure.

FIG. 8 is a circuit diagram of a charge pump and a loop filter according to a third example of the related art.

FIG. 9 is a circuit diagram of a charge pump and a loop filter according to a third embodiment of the present disclosure.

FIGS. 10A and 10B are a circuit diagram illustrating an exemplary phase detector and a timing chart of output signals, respectively.

FIG. 11 is a timing chart principally illustrating waveforms of signals received by a charge pump and of signals output from the charge pump.

FIG. 12 is a waveform diagram in the case where an input data signal is 1UI in the charge pump and the loop filter of FIG. 8 in the related art.

FIG. 13 is a waveform diagram in the case where an input data signal is 1UI in the charge pump and the loop filter of FIG. 9 as the third embodiment of the present disclosure.

FIG. 14 is a waveform diagram comparatively illustrating the current waveforms of FIGS. 12 and 13.

FIG. 15 is a waveform diagram in the case where an input data signal is 2UI in the charge pump and the loop filter of FIG. 8 in the related art.

FIG. 16 is a waveform diagram in the case where an input data signal is 2UI in the charge pump and the loop filter of FIG. 9 in the third embodiment of the present disclosure.

FIG. 17 is a waveform diagram comparatively illustrating the current waveforms of FIGS. 15 and 16.

FIGS. 18A and 18B are each a circuit diagram of a loop filter according to a first example of a fourth embodiment of the present disclosure.

FIGS. 19C and 19D are each a circuit diagram of a loop filter according to a second example of the fourth embodiment of the present disclosure.

FIGS. 20E and 20F are each a circuit diagram of a loop filter according to a third example of the fourth embodiment of the present disclosure.

FIG. 21 is a circuit diagram of a voltage control oscillator according to a first example of a fifth embodiment of the present disclosure.

FIG. 22 is a circuit diagram of a voltage control oscillator according to a second example of the fifth embodiment of the present disclosure.

FIG. 23 is a circuit diagram of a voltage control oscillator according to a third example of the fifth embodiment of the present disclosure.

FIG. 24 is a circuit diagram of a voltage control oscillator according to a fourth example of the fifth embodiment of the present disclosure.

FIG. 25 is a block diagram of a phase locked loop in the related art.

FIG. 26 is a block diagram of CDR in the related art.

FIGS. 27A and 27B are waveform diagrams explaining stationary phase error in a phase locked loop and in CDR, respectively.

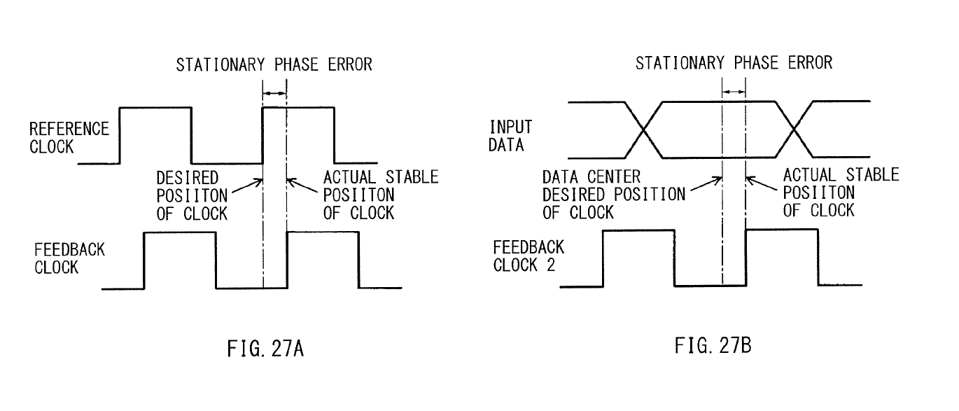

### DETAILED DESCRIPTION

Hereinafter, some embodiments of the present disclosure are described according to the following configuration.

[Operational Principle]

[First Embodiment: Charge Pump and Loop Filter]

[Second Embodiment: Charge Pump and Loop Filter]

[Third Embodiment: Charge Pump and Loop Filter]

[Third Embodiment: Operation of Charge Pump and Loop Filter]

[Fourth Embodiment: Variations of Loop Filter]

[Fifth Embodiment: Variations of Voltage Control Oscillator]

### [Operational Principle]

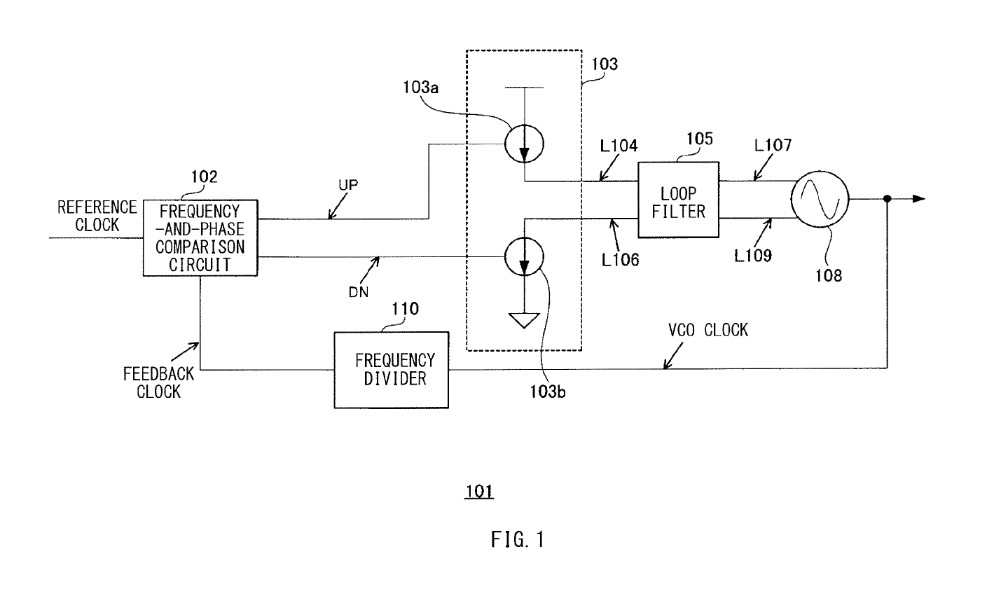

FIG. 1 is a block diagram of a phase locked loop 101 according to an example embodiment of the present disclosure.

A phase/frequency detector 102 compares each of a frequency and a phase of a reference clock to each of those of a feedback clock, and outputs an UP signal and a DN signal each being a PWM control signal based on results of the comparison. The UP signal and the DN signal each being a digital signal are to exclusively perform ON/OFF control of a first current source 103a and of a second current source 103b, respectively, configuring a charge pump 103. Specifically, the charge pump 103 converts such digital signals into current signals.

A charge current output by the first current source 103a is supplied to a loop filter 105 through a first signal line L104.

A discharge current output by the second current source 103b is supplied to the loop filter 105 through a second signal line L106.

The charge current of the first current source 103a and the discharge current of the second current source 103b are each independently subjected to removal of an unnecessary high-frequency component by a loop filter 105, and are each converted from a current signal into a voltage signal.

The charge current of the first current source 103a is supplied to the loop filter 105 through the first signal line L104, and is converted into a first voltage signal by the loop filter 105. The first voltage signal is applied to a voltage control oscillator 108 through a third signal line L107.

The discharge current of the second current source 103b is supplied to the loop filter 105 through the second signal line L106, and is converted into a second voltage signal by the loop filter 105. The second voltage signal is applied to the voltage control oscillator 108 through a fourth signal line L109.

The first voltage signal and the second voltage signal are each independently sent to the voltage control oscillator 108 to control an oscillation frequency of the voltage control oscillator 108.

The voltage control oscillator 108 outputs a VCO clock of which the oscillation frequency is controlled based on the received voltage signals. The VCO clock is divided in frequency into a predetermined frequency by the frequency divider 110, and is then sent to the phase/frequency detector 102.

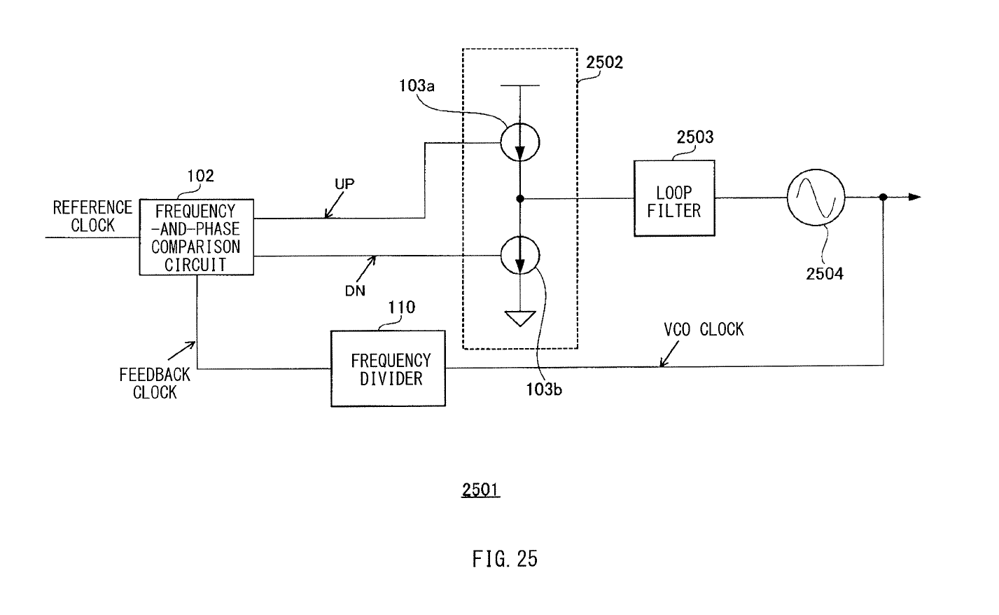

The phase locked loop 101 is different in the following points from the phase locked loop 101 of FIG. 25 in the related art.
The charge current of the first current source 103a configuring the charge pump 103 flows through the first signal line L104, while the discharge current of the second current source 103b flows through the second signal line L106. The charge current and the discharge current are thus independent of each other.
The loop filter 105 receives the charge current through the first signal line L104 and the discharge current through the second signal line L106, and independently outputs the first voltage signal through the third signal line L107 and the second voltage signal through the fourth signal line L109.
The voltage control oscillator 108 receives the first voltage signal through the third signal line L107 and the second voltage signal through the fourth signal line L109 so as to be controlled in oscillation frequency of the VCO clock.

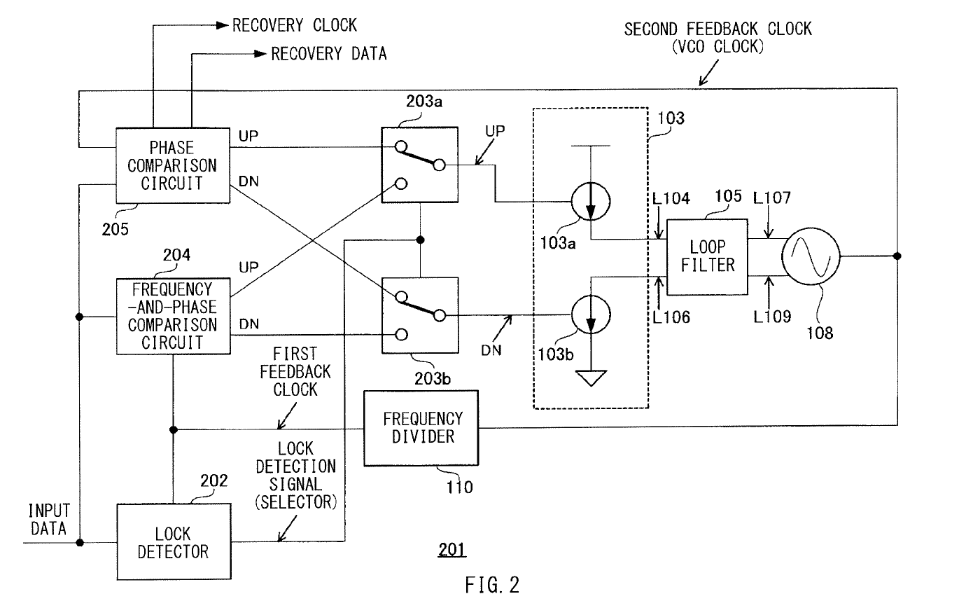

FIG. 2 is a block diagram of CDR 201 according to an example embodiment of the present disclosure.

A lock detector 202 compares each of a frequency and a phase of an input data signal to each of those of a first feedback clock output from the frequency divider 110 to determine whether a frequency difference and a phase difference are each within a lock range of a phase detector. When the difference is not within the lock range, output of each of multiplexers 203a and 203b is selected to be on a phase/frequency detector 204 side. When the difference is within the lock range, output of each of multiplexers 203a and 203b is selected to be on a phase detector 205 side.

The phase/frequency detector 204 compares each of a frequency and a phase of an input data signal to each of those of the first feedback clock, and outputs an UP signal and a DN signal each being a PWM control signal based on results of the comparison. The charge pump 103 outputs a current based on the UP signal and the DN signal received via the multiplexers 203a and 203b. Specifically, the charge pump 103 converts the digital signals into current signals.

The charge current output by the first current source 103a is supplied to the loop filter 105 through the first signal line L104.

The discharge current output by the second current source 103b is supplied to the loop filter 105 through the second signal line L106.

The charge current of the first current source 103a and the discharge current of the second current source 103b are each independently subjected to removal of an unnecessary high-frequency component by the loop filter 105, and are each converted from a current signal into a voltage signal.

The charge current of the first current source 103a is supplied to the loop filter 105, and is converted into the first voltage signal by the loop filter 105. The first voltage signal is applied to the voltage control oscillator 108 through the third signal line L107.

The discharge current of the second current source 103b is supplied to the loop filter 105, and is converted into the second voltage signal by the loop filter 105. The second voltage signal is applied to the voltage control oscillator 108 through the fourth signal line L109.

The first voltage signal and the second voltage signal are each independently sent to the voltage control oscillator 108 to control the oscillation frequency of the voltage control oscillator 108.

The voltage control oscillator 108 outputs a second feedback clock (VCO clock) of which the oscillation frequency is controlled based on the received voltage signals. The second feedback clock is sent to the phase detector 205, and is divided in frequency into a predetermined frequency by the frequency divider 110, and is then sent to the phase/frequency detector 204.

The phase detector 205 compares each of a frequency and a phase of the input data signal to each of those of the second feedback clock, and outputs an UP signal and a DN signal each being a PWM control signal based on results of the comparison, as with the phase/frequency detector 204. The UP signal and the DN signal each being a digital signal are received by the multiplexers 203a and 203b, respectively. Signal processing of the multiplexers 203a and 203b or in later stages is similar to signal processing of the phase/frequency detector 204. The phase detector 205 outputs a recovery clock having a frequency equal to that of the second feedback clock, and recovery data having a phase in synchronization with a phase of the recovery clock. While a lock detection signal output by the lock detector 202 controls the multiplexers 203a and 203b to be on the phase detector side, the recovery clock and the recovery data are processed by a subsequent circuit, thereby original data is allowed to be extracted from the input data signal.

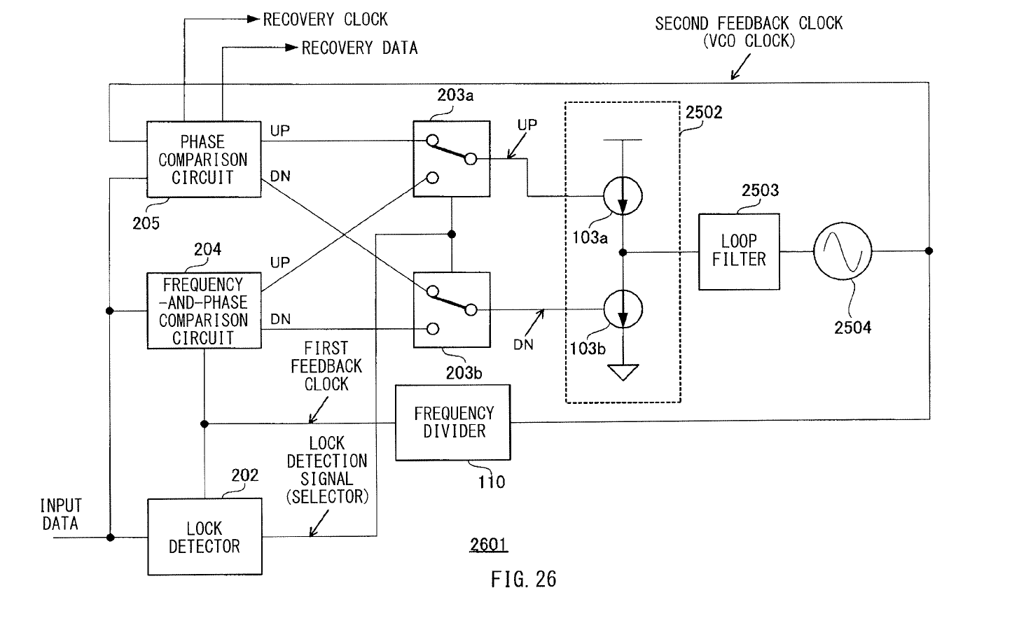

The CDR 201 is different in the following points from the CDR 201 of FIG. 26 in the related art.
The charge current of the first current source 103a configuring the charge pump 103 flows through the first signal line L104, while the discharge current of the second current source 103b flows through the second signal line L106. The charge current and the discharge current are thus independent of each other.
The loop filter 105 receives the charge current through the first signal line L104 and the discharge current through the second signal line L106, and independently outputs the first voltage signal through the third signal line L107 and the second voltage signal through the fourth signal line L109.
The voltage control oscillator 108 receives the first voltage signal through the third signal line L107 and the second voltage signal through the fourth signal line L109 so as to be controlled in oscillation frequency of the VCO clock.

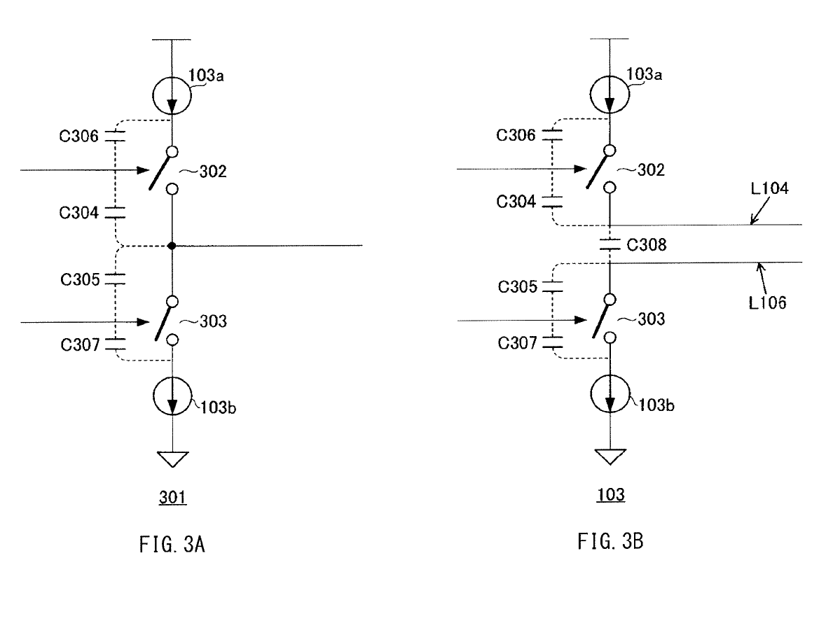

FIGS. 3A and 3B are schematic diagrams illustrating a difference between a charge pump 301 in the related art and the charge pump 103 as an example embodiment of the present disclosure.

FIG. 3A is a schematic diagram of the charge pump 301 in the related art. An output signal of the charge pump 301 is transmitted through a single signal line. Therefore, since the first current source 103a and the second current source 103b are connected via a first switch 302 and a second switch 303, mismatch may occur by a shoot-through current depending on a state of each of the first switch 302 and the second switch 303. The first switch 302 and the second switch 303 are each configured of MODFET, and include parasitic capacitances C304, C305, C306, and C307 between a gate of the first switch 302 and a drain or source of the second switch 303. Due to existence of such parasitic capacitances C304, C305, C306, and C307, the switching signal, which is to control each of the first switch 302 and the second switch 303, affects the charge current output by the first current source 103a and the discharge current output by the second current source 103b through the parasitic capacitances.

FIG. 3B is a schematic diagram of the charge pump 103 as an example embodiment of the present disclosure. Output signals of the charge pump 103 are transmitted through two signal lines, i.e., the first signal line L104 and the second signal line L106. Specifically, output of the first current source 103a is separated from output of the second current source 103b; hence, a shoot-through current is basically not generated. In addition, such two separated signal lines causes a parasitic capacitance C308 between the first signal line L104 and the second signal line L106, i.e., between the parasitic capacitances C304 and C305. This increases impedance between a switching signal of the first switch 302 and the second signal line L106, and thus decreases influence of the switching signal of the first switch 302 on the discharge current output by the second current source 103b. Similarly, the existence of the parasitic capacitance C308 increases impedance between a switching signal of the second switch 303 and the first signal line L104, and thus decreases influence of the switching signal of the second switch 303 on the discharge current output by the first current source 103a.

### First Embodiment

### Charge Pump 501 and Loop Filter 502

The charge pump 103 and the loop filter 105 of the CDR 201 according to an example embodiment of the present disclosure are now described in comparison to those in the related art.

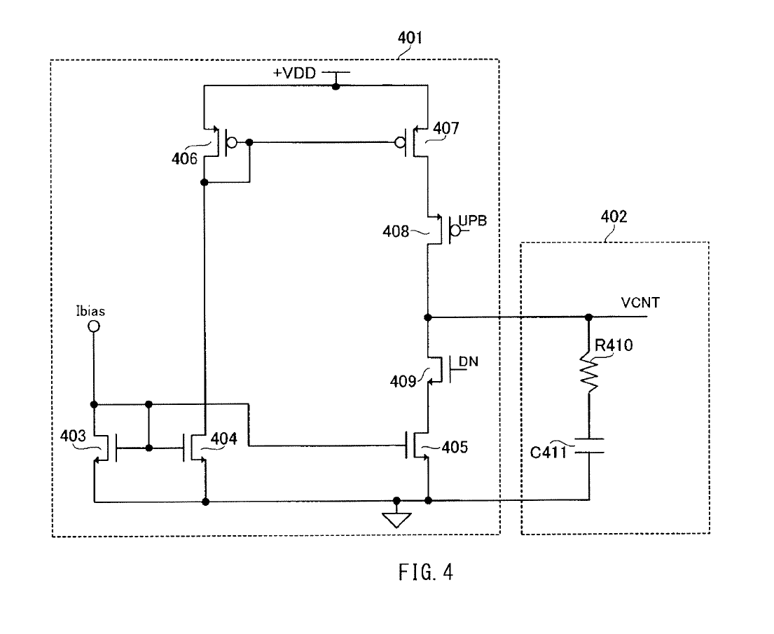

FIG. 4 is a circuit diagram of a charge pump 401 and a loop filter 402 according to a first example of the related art. Hereinafter, N-channel MOSFET is abbreviated as NMOSFET, and P-channel MOSFET is abbreviated as PMOSFET.

NMOSFET 403 receives a bias current Ibias, and supplies a bias voltage to NMOSFET 405 through a gate voltage of NMOSFET 404.

The NMOSFET 405 serves as the second current source 103b in FIG. 2 that is to supply the discharge current.

The drain of the NMOSFET 404 is connected to the drain of PMOSFET 406. The source of the PMOSFET 406 is connected to a power supply+VDD, and supplies a bias voltage to the gate of PMOSFET 407.

The PMOSFET 407 serves as the first current source 103a in FIG. 2 that is to supply the charge current.

PMOSFET 408, which severs as the first switch 302 in FIG. 2 that is to control a current of the first current source 103a, receives an UPB signal as a signal produced by inverting logic of the UP signal with an undepicted NOT gate so as to be controlled to be ON or OFF.

The NMOSFET 409, which serves as the second switch 303 in FIG. 2 that is to control a current of the second current source 103b, receives the DN signal so as to be controlled to be ON or OFF.

The drain of the PMOSFET 408 and the drain of the NMOSFET 409 are each connected to a resistance R410 of the loop filter 402 and are continued to the undepicted subsequent voltage control oscillator 108. The resistance R410 is connected to a first end of a capacitor C411. A second end of the capacitor C411 is grounded together with the source of the NMOSFET 403, the source of the NMOSFET 404, and the source of the NMOSFET 405.

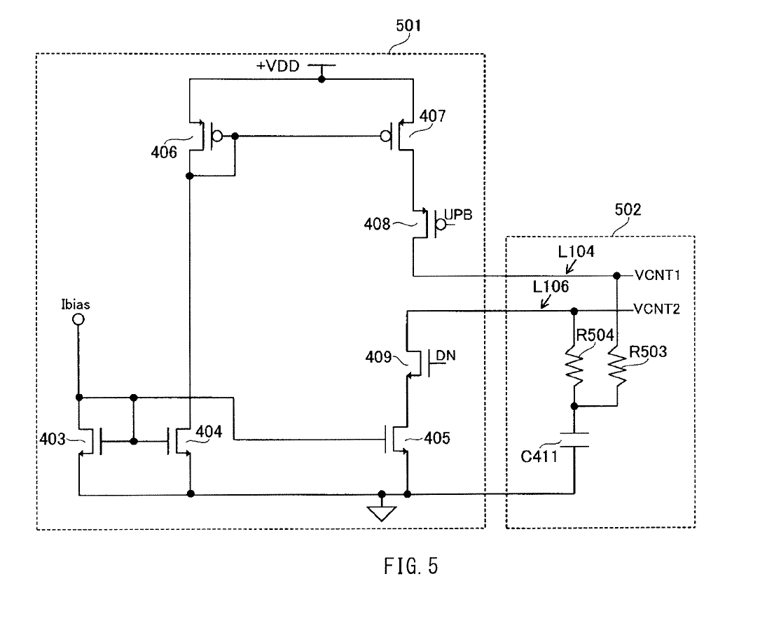

FIG. 5 is a circuit diagram of a charge pump 501 and a loop filter 502 according to a first embodiment of the present disclosure.

The circuit of FIG. 5 is different from the circuit of FIG. 4 in the following points.
First, the drain of the PMOSFET 408 is connected to a resistance R503 and is continued to the undepicted subsequent voltage control oscillator 108, but is not connected to the drain of the NMOSFET 409 and a resistance R504.
Second, the drain of the NMOSFET 409 is connected to the resistance R504 and is continued to the undepicted subsequent voltage control oscillator 108, but is not connected to the drain of the PMOSFET 408 and the resistance R503.
A second end of the resistance R503 and a second end of the resistance R504 are each connected to the capacitor C411.

Specifically, the charge current of the first current source 103a (PMOSFET 407) is output through the first signal line L104, and the discharge current of the second current source 103b (NMOSFET 405) is output through the second signal line L106. Hence, the charge current and the discharge current are separated from each other. As a result, influence of mismatch due to the shoot-through current is reduced.

### Second Embodiment

### Charge Pump 701 and Loop Filter 702

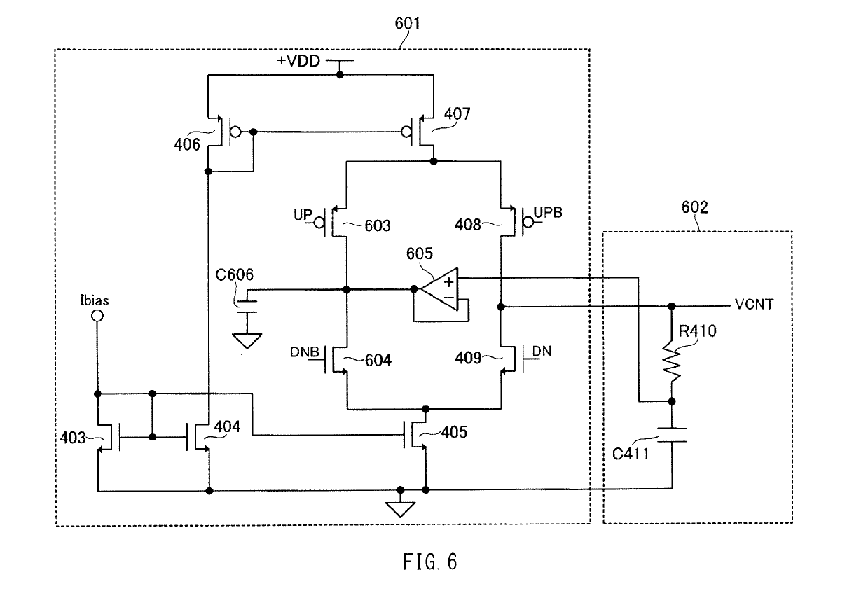

FIG. 6 is a circuit diagram of a charge pump 601 and a loop filter 602 according to a second example of the related art.

The circuit of FIG. 6 is different from the circuit of FIG. 4 in the following points.
PMOSFET 603, which is controlled to be ON or OFF with a logic (an UP signal) opposite to logic of the PMOSFET 408, is provided to equalize operation of the first current source 103a (PMOSFET 407).
NMOSFET 604, which is controlled to be ON or OFF with a logic opposite to logic of the NMOSFET 409 (with a DNB signal produced by inverting logic of the DN signal with an undepicted NOT gate), is provided to equalize operation of the second current source 103b (NMOSFET 405).
A connected point of a resistance R410 and the capacitor C411 is connected to the drain of the PMOSFET 603 and the drain of the NMOSFET 604 through a voltage follower configured of an operational amplifier 605, and is in turn grounded via a capacitor 606.

In this way, the PMOSFET 603 and the NMOSFET 604 are additionally provided, thereby the PMOSFET 407 as the first current source 103a and the NMOSFET 405 as the second current source 103b each perform continuous current flow operation, leading to a decrease in variation of the current. Furthermore, a connected point of the drain of the PMOSFET 603 and the drain of the NMOSFET 604 is AC-grounded via the capacitor C606 while a voltage of the connected point is stabilized by the voltage follower. This improves stability of each of the PMOSFET 407 as the first current source 103a and the NMOSFET 405 as the second current source 103b.

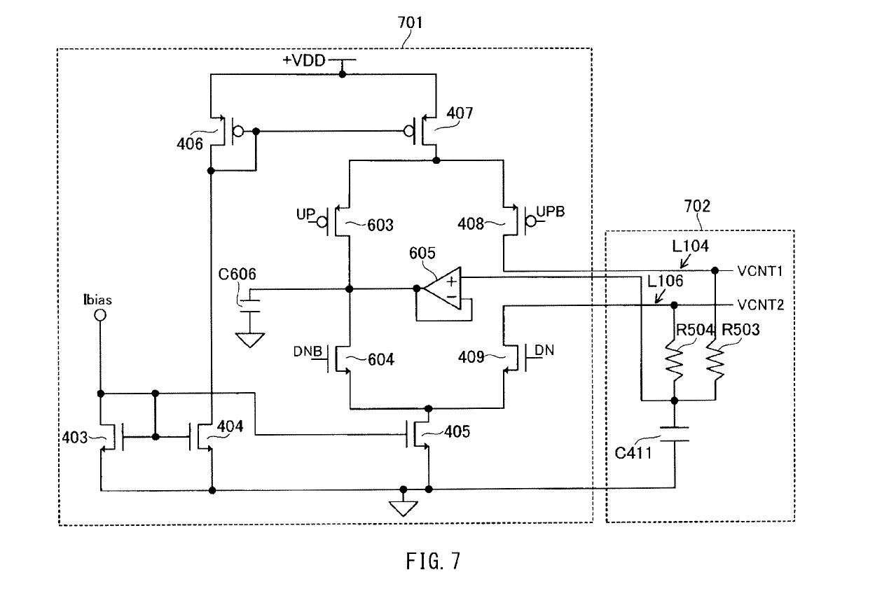

FIG. 7 is a circuit diagram of a charge pump 701 and a loop filter 702 according to a second embodiment of the present disclosure.

The circuit of FIG. 7 is different from the circuit of FIG. 6 in the following points.
First, the drain of the PMOSFET 408 is connected to the resistance R503 and is continued to the undepicted subsequent voltage control oscillator 108, but is not connected to the drain of the NMOSFET 409 and the resistance R504.
Second, the drain of the NMOSFET 409 is connected to the resistance R504 and is continued to the undepicted subsequent voltage control oscillator 108, but is not connected to the drain of the PMOSFET 408 and the resistance R503.
A second end of the resistance R503 and a second end of the resistance R504 are each connected to the capacitor C411.

Specifically, the charge current of the first current source 103a (PMOSFET 407) is output through the first signal line L104, and the discharge current of the second current source 103b (NMOSFET 405) is output through the second signal line L106. Hence, the charge current and the discharge current are separated from each other.

### Third Embodiment

### Charge Pump 901 and Loop Filter 902

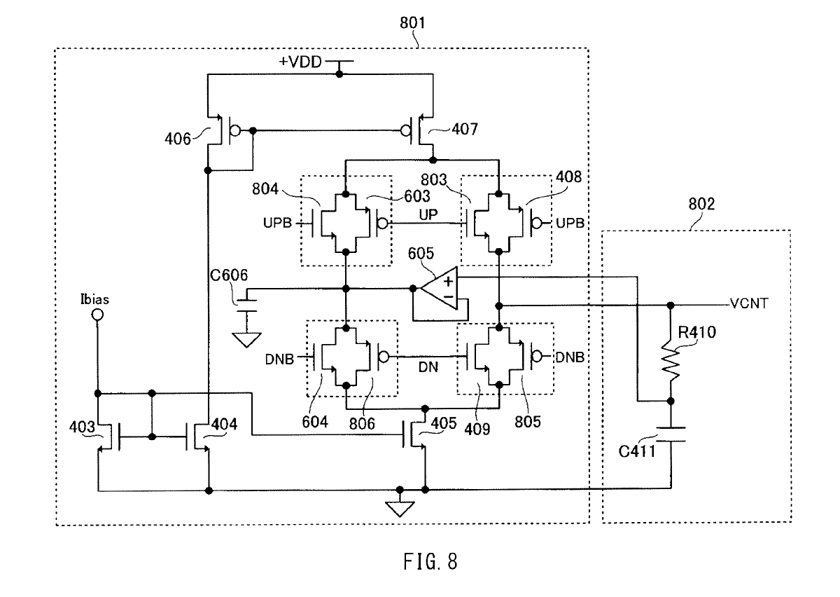

FIG. 8 is a circuit diagram of a charge pump 801 and a loop filter 802 according to a third example of the related art.

The circuit of FIG. 8 is different from the circuit of FIG. 6 in the following points.
The PMOSFET 408, the PMOSFET 603, the NMOSFET 409, and the NMOSFET 604 are each formed into a CMOS structure. A drain and a source of NMOSFET 803 are connected in parallel between the source and the drain of the PMOSFET 408, a drain and a source of NMOSFET 804 are connected in parallel between the source and the drain of the PMOSFET 603, a drain and a source of PMOSFET 805 are connected in parallel between the source and the drain of the NMOSFET 409, and a drain and a source of PMOSFET 806 are connected in parallel between the source and the drain of the NMOSFET 604. The circuit configured in this way is controlled as follows.
The gate of each of the PMOSFET 603 and the NMOSFET 803 is controlled by the UP signal.
The gate of each of the NMOSFET 804 and the PMOSFET 408 is controlled by the UPB signal.
The gate of each of the PMOSFET 806 and the NMOSFET 409 is controlled by the DN signal.
The gate of each of the NMOSFET 604 and the PMOSFET 805 is controlled by the DNB signal.

Such improvement in symmetry of each MOSFET suppresses variation in the circuit.

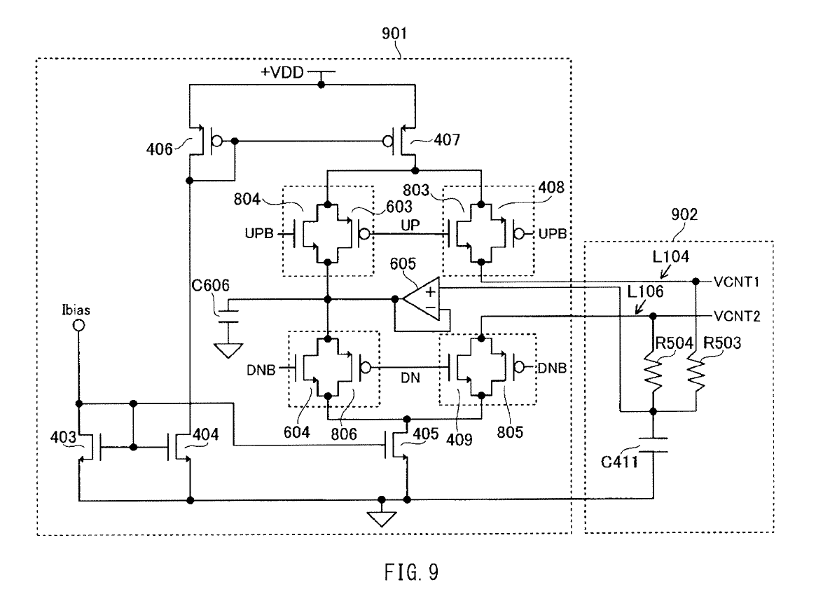

FIG. 9 is a circuit diagram of a charge pump 901 and a loop filter 902 according to a third embodiment of the present disclosure.

The circuit of FIG. 9 is different from the circuit of FIG. 8 in the following points.
First, the drain of the PMOSFET 408 is connected to the resistance R503 and is continued to the undepicted subsequent voltage control oscillator 108, but is not connected to the drain of the NMOSFET 409 and the resistance R504.
Second, the drain of the NMOSFET 409 is connected to the resistance R504 and is continued to the undepicted subsequent voltage control oscillator 108, but is not connected to the drain of the PMOSFET 408 and the resistance R503.
A second end of the resistance R503 and a second end of the resistance R504 are each connected to the capacitor C411.

Specifically, the charge current of the first current source 103a (PMOSFET 407) is output through the first signal line L104, and the discharge current of the second current source 103b (NMOSFET 405) is output through the second signal line L106. Hence, the charge current and the discharge current are separated from each other.

### Third Embodiment

### Operation of Charge Pump 901 and Loop Filter 902

Electric characteristics of each of the charge pump 901 and the loop filter 902 according to the third embodiment as illustrated in FIG. 9 are now described.

First, description is made on behavior of the charge pump 103 for the UP signal and the DN signal that are output from the phase detector 205 and applied to the charge pump 103, and for an input data signal received by the CDR201.

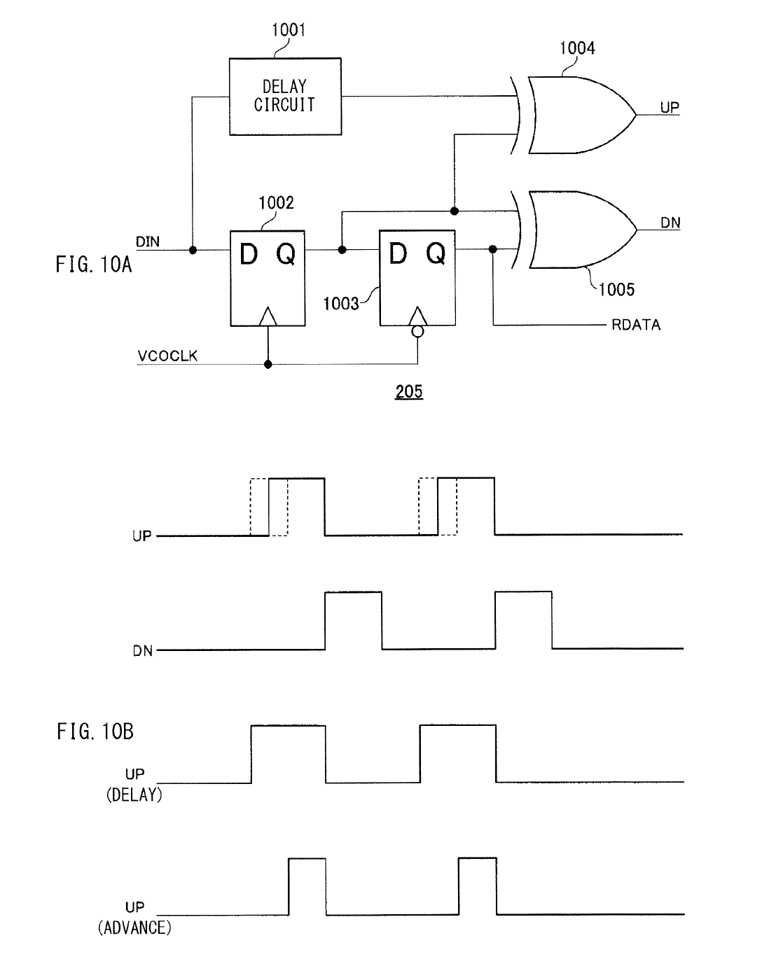

FIG. 10A is a circuit diagram illustrating an exemplary phase detector 205, and FIG. 10B is a timing chart of the output signals from the phase detector 205.

FIG. 10A is the circuit diagram illustrating the exemplary phase detector 205.

An input data signal DIN is received by a delay circuit 1001 and by a D terminal of a first D flip-flop 1002. A clock signal VCOCLK is received by a clock terminal of the first D flip-flop 1002, and by a clock terminal of a second D flip-flop 1003 while being inverted in logic.

A Q output signal of the first D flip-flop 1002 and an output signal of the delay circuit 1001 are received by a first exclusive OR gate 1004. An output signal of the first exclusive OR gate 1004 is an UP signal for phase advancement.

The Q output signal of the first D flip-flop 1002 and a Q output signal of the second D flip-flop 1003 are received by a second exclusive OR gate 1005. An output signal of the second exclusive OR gate 1005 is a DN signal for phase delay. The Q output signal of the second D flip-flop 1003 is also used as a reproduction data signal RDATA.

FIG. 10B is the timing chart of the output signals of the phase detector 205.

When a phase of the input data signal DIN is equal to a phase of the clock signal VCOCLK, a pulse width of the UP signal is equal to a pulse width of the DN signal.

When the phase of the clock signal VCOCLK advances with respect to the phase of the input data signal DIN, the pulse width of the UP signal becomes narrower than the pulse width of the DN signal.

When the phase of the clock signal VCOCLK delays with respect to the phase of the input data signal DIN, the pulse width of the UP signal becomes wider than the pulse width of the DN signal.

On the other hand, the pulse width of the DN signal is typically equal to pulse width of the clock signal VCOCLK regardless of variation in phase of each of the input data signal DIN and the clock signal VCOCLK.

In this way, the phase difference between the input data signal DIN and the clock signal VCOCLK is output in a form of a difference in pulse width between the UP signal and the DN signal output by the phase detector 205.

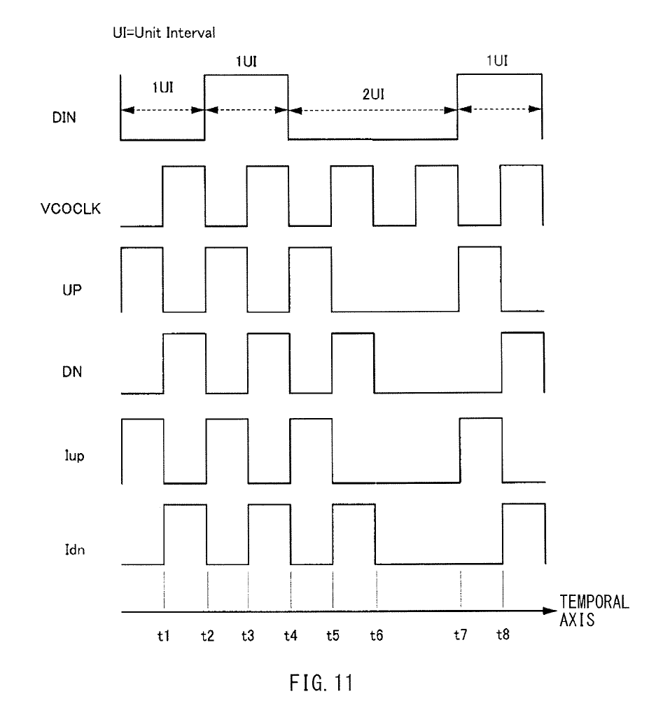

FIG. 11 is a timing chart principally illustrating a waveform of a signal received by the charge pump 103 and a waveform of a signal output from the charge pump 103.

The input data signal DIN is a signal having an interval as an integral number of the unit interval UI.

On the other hand, the clock signal VCOCLK is in synchronization with a cycle of 1UI, i.e., is a signal having a cycle of 1UI.

When data length of the input data signal DIN is 1UI, the DN signal has a waveform that is equal to a waveform of the clock signal VCOCLK, and the UP signal has a waveform that is inverted in phase by 180° from the waveform of the DN signal (time points t2, t3, and t4).

When the data length of the input data signal DIN is 2UI or more, the DN signal has a waveform that is equal to the waveform of the clock signal VCOCLK only in one cycle of a clock signal VCOCLK having an edge equal to a first edge of the input data signal DIN (time points t4, t5, and t6), and thereafter the DN signal maintains a low potential until a subsequent edge of the input data signal DIN (time points t6 and t7).

On the other hand, the UP signal outputs a waveform that is inverted in phase by 180° from the waveform of the DN signal, the waveform of the DN signal being equal to the waveform of the clock signal VCOCLK only in one cycle of the clock signal VCOCLK having the edge equal to a first edge of the input data signal DIN (time points t4, t5, and t6), and thereafter the UP signal maintains a low potential until a subsequent edge of the input data signal DIN (time points t6 and t7).

A charge current Iup output from the first current source 103a (PMOSFET 407) is principally equal in phase to the UP signal.

Similarly, a discharge current Idn output from the second current source 103b (NMOSFET 405) is principally equal in phase to the DN signal.

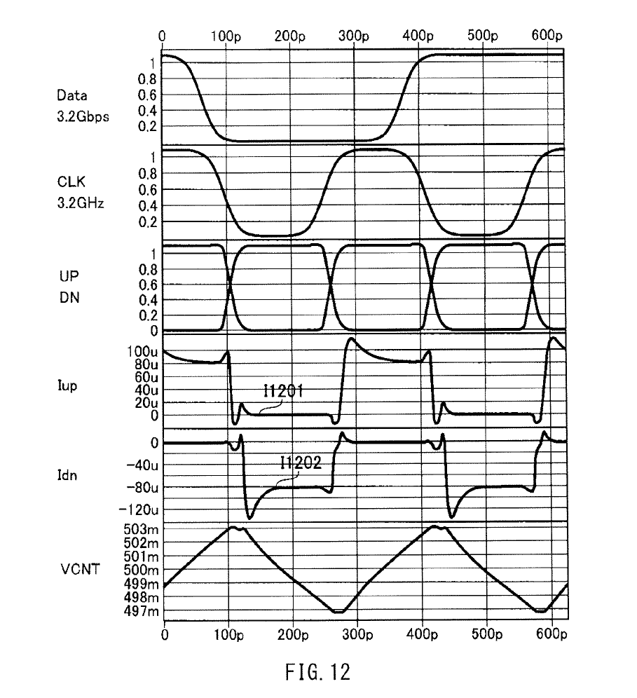

FIG. 12 is a waveform diagram in the case where the input data length is 1UI in the charge pump 801 and the loop filter 802 of FIG. 8 in the related art. FIG. 12 illustrates results of measurement by an actual circuit in a period from the time point t1 to the time point t4 in the timing chart of FIG. 11.

The UP signal and the DN signal are each shown duller in rising and falling on a temporal axis with an increase in frequency of the clock signal VCOCLK. Specifically, a slight shoot-through current, which passes through the first current source 103a (PMOSFET 407) and the second current source 103b (NMOSFET 405), occurs at a moment when logic of each of the UP signal and the DN signal is switched. In addition, a clock feed-through phenomenon occurs at such a time point. Influence of such a shoot-through current and a clock feed-through phenomenon may be shown in a form of distortion of the waveform of each of the charge current Iup (I1201) and the discharge current Idn (I1202). Such distortion of the waveform results in output current mismatch between the two current sources. The mismatch affects a voltage signal VCNT, and consequently shifts the frequency of the clock signal VCOCLK. The phase detector 20 operationally maintains the frequency to be constant with a stationary phase offset in order to compensate such a frequency shift. As a result, the clock is prevented from tapping data.

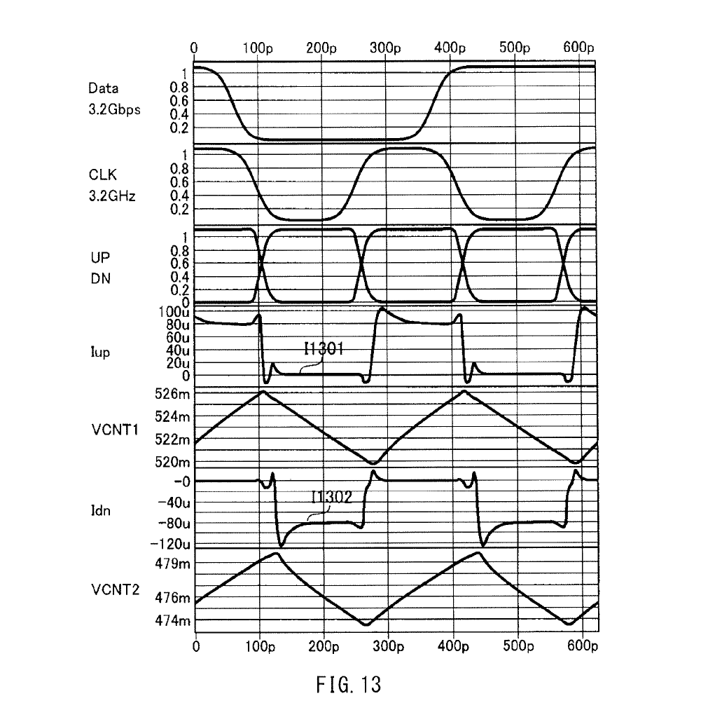

FIG. 13 is a waveform diagram in the case where the input data length is 1UI in the charge pump 901 and the loop filter 902 of FIG. 9 of the third embodiment of the present disclosure.

When compared to FIG. 12, the shoot-through current, which passes through the first current source 103a (PMOSFET 407) and the second current source 103b (NMOSFET 405), may not principally occur, and the clock feed-through phenomenon is reduced due to a decrease in parasitic capacitance. Hence, the distortion, which may occur at a moment when logic of each of the UP signal and the DN signal is switched, is decreased.

Influence of such elimination of the shoot-through current and the reduction in clock feed-through phenomenon is shown as a decrease in distortion of the waveform of each of the charge current Iup (I1301) and the discharge current Idn (I1302). In addition, such influence is also shown in a voltage signal VCNT1 produced after passing of the charge current Iup through the loop filter 105 and in a voltage signal VCNT2 produced after passing of the discharge current Idn through the loop filter 105. As a result, each of the voltage signal VCNT1 and the voltage signal VCNT2 has a beautiful saw-tooth waveform having substantially no distortion at its apex.

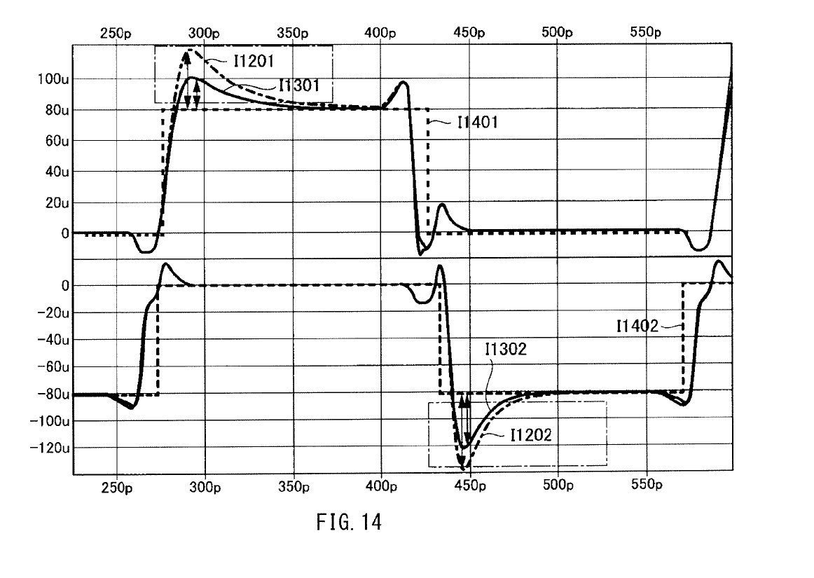

FIG. 14 is a waveform diagram comparatively illustrating the current waveforms of FIGS. 12 and 13. In FIG. 14, the upper waveform is a waveform of Iup, while the lower waveform is a waveform of Idn.

With the charge current Iup, when the charge current I1201 according to the related art is compared to the charge current I1301 according to the third embodiment, potential difference due to the distortion occurring at switching of logic is seen to be decreased. It is to be noted that I1401 represents an ideal waveform for reference.

With the discharge current Idn, when the discharge current I1202 according to the related art is compared to the discharge current I1302 according to the third embodiment, potential difference due to the distortion occurring at switching of logic is seen to be decreased. It is to be noted that I1402 represents an ideal waveform for reference.

Both the waveforms of the charge current Iup and the discharge current Idn are seen to be decreased, compared with those in the related art, in potential difference due to the distortion occurring at switching of logic.

In this way, use of the charge pump 901 and the loop filter 902 according to the third embodiment of the present disclosure improves quality of the current waveform.

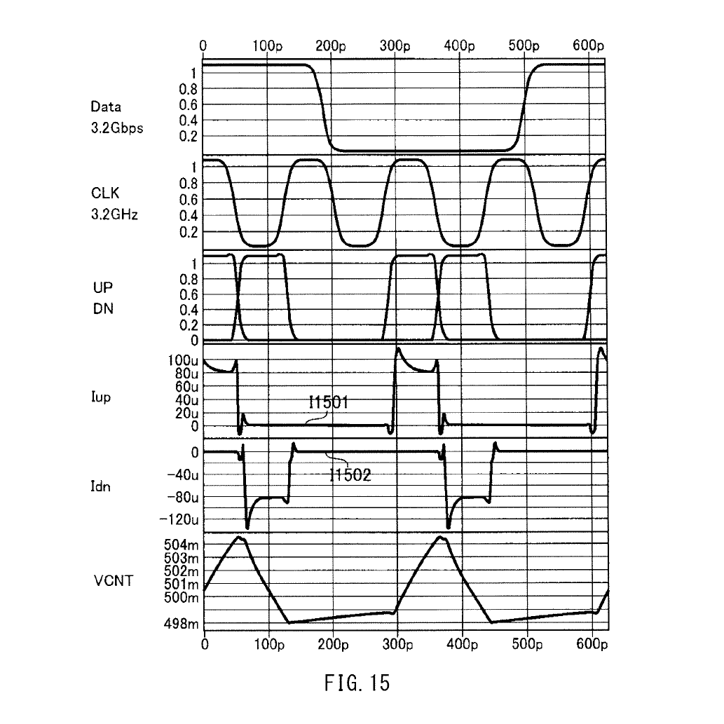

FIG. 15 is a waveform diagram in the case where the input data length is 2UI in the charge pump 801 and the loop filter 802 of FIG. 8 in the related art. FIG. 15 illustrates results of measurement by an actual circuit in a period from the time point t4 to the time point t7 in the timing chart of FIG. 11.

Although the voltage signal VCNT is varied along with an increased unit interval of the input data signal, when a charge current Iup (I1501) and a discharge current Idn (I1502) are each noticed, distortion at a peak portion thereof is similar to that in FIG. 12.

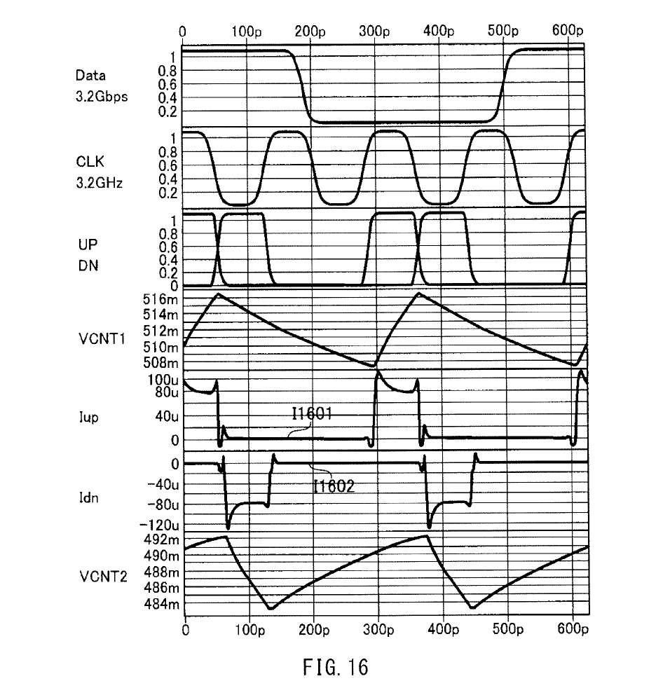

FIG. 16 is a waveform diagram in the case where the input data length is 2UI in the charge pump 901 and the loop filter 902 of FIG. 9 of the third embodiment of the present disclosure.

When compared to the voltage signal VCNT in FIG. 15, a voltage signal VCNT1 and a voltage signal VCNT2 in FIG. 16 are each seen to have a fine saw-tooth waveform having substantially no distortion at its apex.

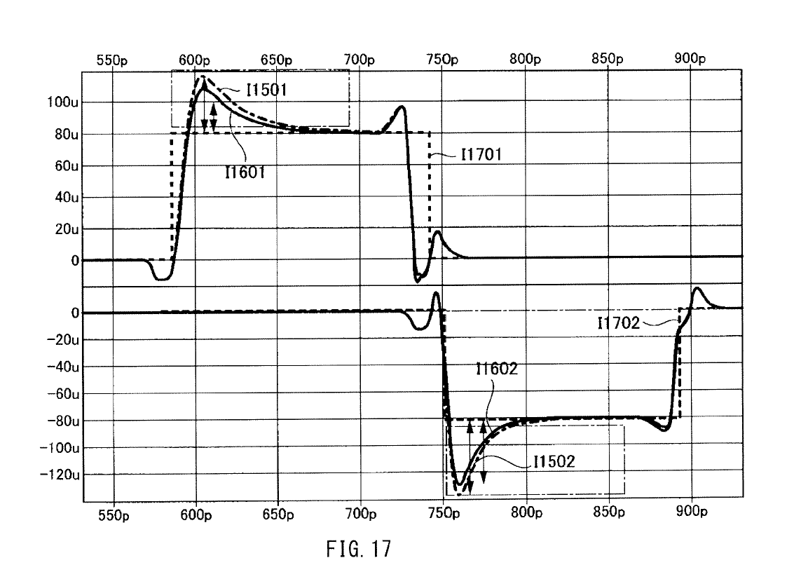

FIG. 17 is a waveform diagram comparatively illustrating the current waveforms of FIGS. 15 and 16. In FIG. 17, the upper waveform is a waveform of Iup, while the lower waveform is a waveform of Idn.

With the charge current Iup, when the charge current I1501 according to the related art is compared to the charge current I1601 according to the third embodiment, a potential difference due to the distortion occurring at switching of logic is seen to be decreased. It is to be noted that I1701 represents an ideal waveform for reference.

With the discharge current Idn, when the discharge current I1502 according to the related art is compared to the discharge current I1502 according to the third embodiment, a potential difference due to the distortion occurring at switching of logic is seen to be decreased. It is to be noted that I1702 represents an ideal waveform for reference.

Both the charge current Iup and the discharge current Idn are seen to be decreased, compared with the related art, in potential difference due to the distortion occurring at switching of logic.

In this way, use of the charge pump 901 and the loop filter 902 according to the third embodiment of the present disclosure improves quality of the current waveform.

### Fourth Embodiment

### Variations of Loop Filter

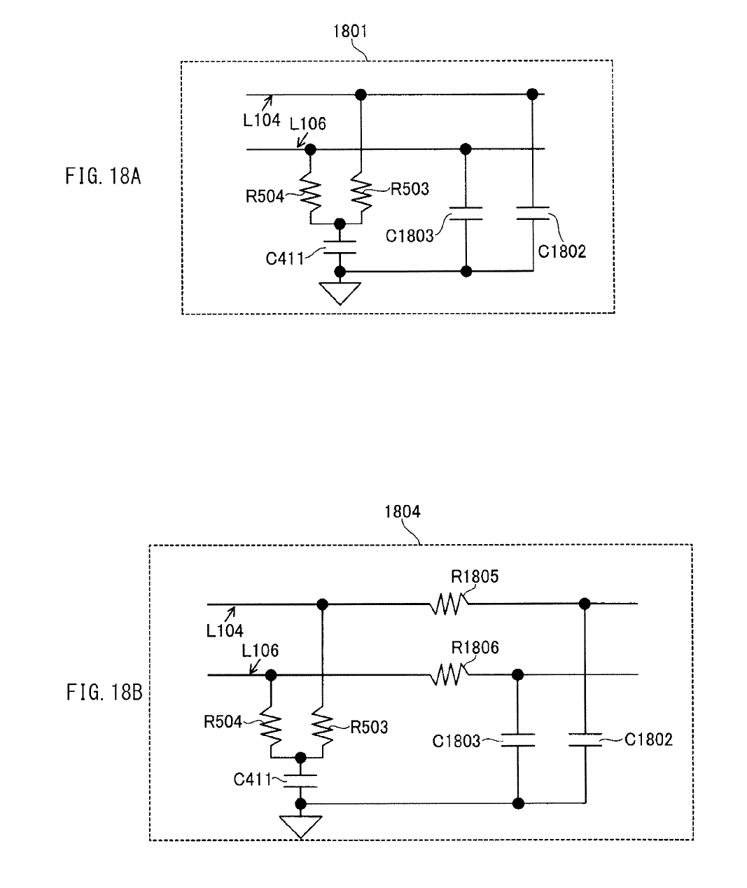

FIGS. 18A and 18B, FIGS. 19C and 19D, and FIGS. 20E and 20F are circuit diagrams of loop filters 105 according to a first example, a second example, and a third example of a fourth embodiment of the present disclosure.

FIG. 18A is a circuit diagram of a loop filter 1801 as a secondary loop filter produced by further adding capacitors C1802 and C1803 to the loop filter 502 disclosed in FIG. 5.

FIG. 18B is a circuit diagram of a loop filter 1804 as a secondary loop filter produced by further adding resistances R1805 and R1806 to the loop filter 1801 of FIG. 18A.

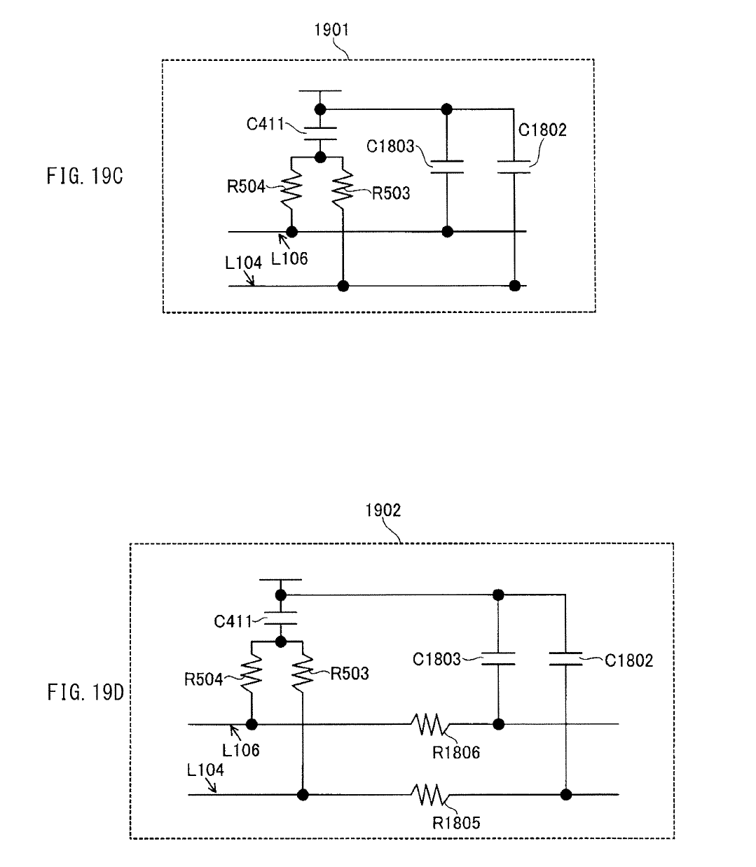

FIG. 19C is a circuit diagram of a loop filter 1901 as a variation of the loop filter 1801 disclosed in FIG. 18A, in which ground base is changed to power base.

FIG. 19D is a circuit diagram of a loop filter 1902 as a variation of the loop filter 1804 disclosed in FIG. 18B, in which ground base is changed to power base.

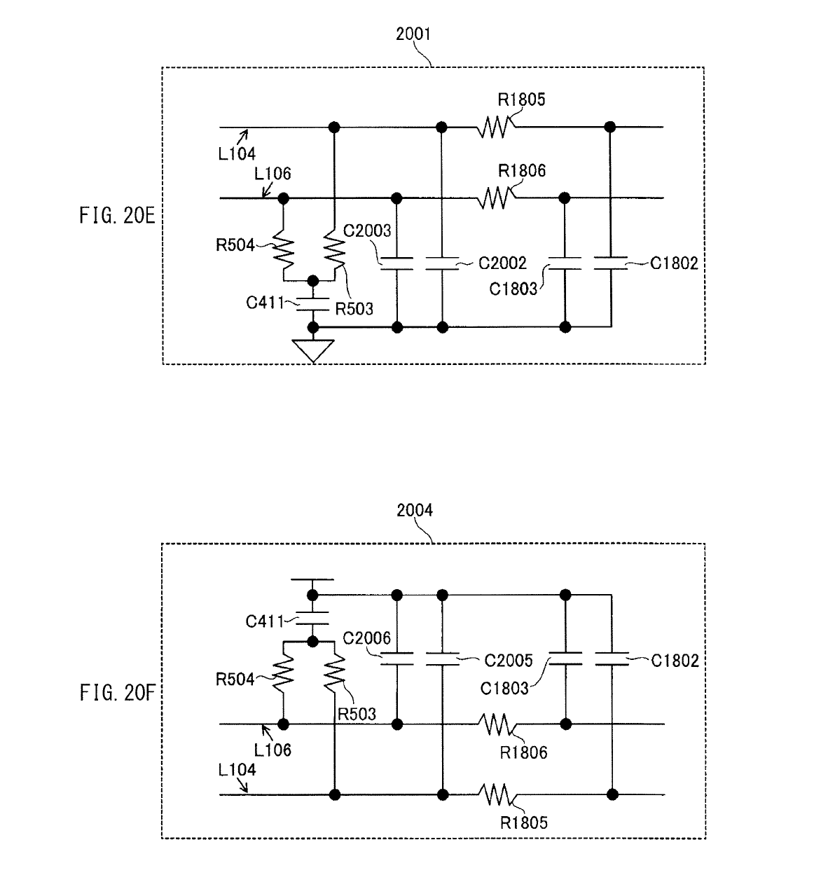

FIG. 20E is a circuit diagram of a loop filter 2001 as a tertiary loop filter produced by further adding capacitors C2002 and C2003 to the loop filter 1804 disclosed in FIG. 18B.

FIG. 20F is a circuit diagram of a loop filter 2004 as a tertiary loop filter produced by further adding capacitors C2005 and C2006 to the loop filter 1902 disclosed in FIG. 19D.

### Fifth Embodiment

### Variations of Voltage Control Oscillator

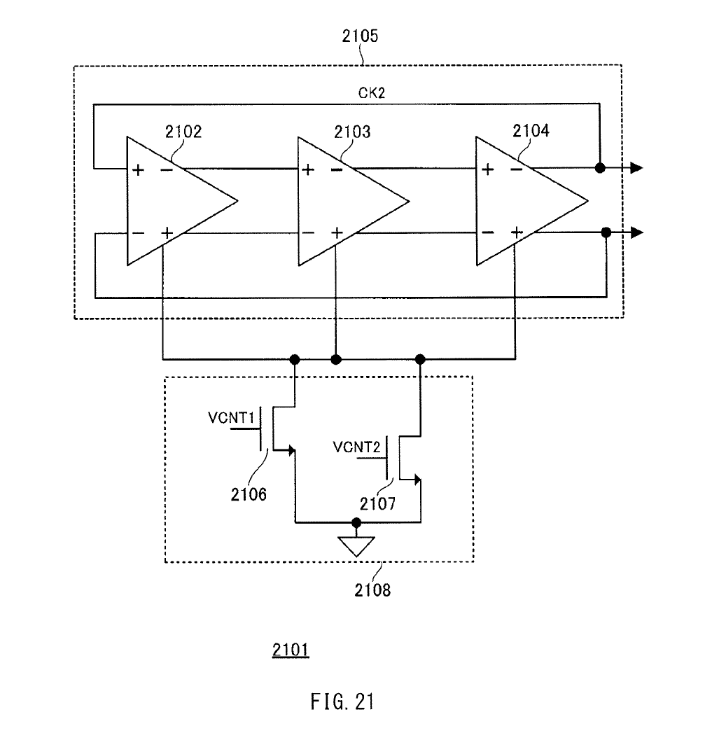

FIGS. 21, 22, 23, and 24 are circuit diagrams of voltage control oscillators according to a first example, a second example, a third example, and a fourth example of a fifth embodiment of the present disclosure.

First, a voltage control oscillator 2101 of FIG. 21 is described.

In each of fully differential operational amplifiers 2102, 2103, and 2104, an inverted output terminal is connected to a non-inverted input terminal in a subsequent stage, and a non-inverted output terminal is connected to an inverted input terminal in a subsequent stage. A ring oscillator 2105 is configured through such connection of the input terminals and the output terminals in a positive feedback state. Gain terminals of the fully differential operational amplifiers 2102, 2103, and 2104 configuring the ring oscillator 2105 are connected to NMOSFET 2106 configured to be driven by a voltage control signal VCNT1 and a NMOSFET 2107 configured to be driven by a voltage control signal VCNT2. The NMOSFET 2106 and the NMOSFET 2107 configure a voltage-current conversion circuit 2108 configured to convert a voltage signal into a current signal.

Increase or decrease in control current flowing through the NMOSFET 2106 with respect to a control current flowing through the NMOSFET 2107 causes increase or decrease in oscillation frequency of the ring oscillator 2105.

Voltage control signals VCNT1 and VCNT2 are completely separated from each other by the NMOSFET 2106 and the NMOSFET 2107; hence, the shoot-through current, which passes through the first current source 103a (PMOSFET 407) and the second current source 103b (NMOSFET 405), may not principally occur, and the clock feed-through phenomenon is reduced.

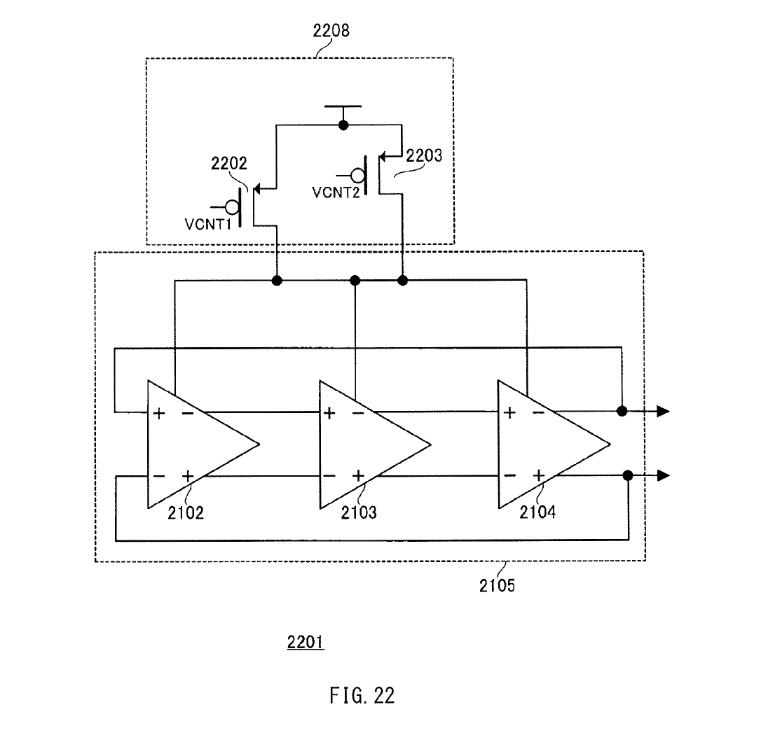

FIG. 22 illustrates a voltage control oscillator 2201 as a variation of the voltage control oscillator 2101 illustrated in FIG. 21, in which ground base is changed to power base. Although MOSFETs for gain adjustment are changed to PMOSFET 2102 and PMOSFET 2103, the operational principle of the voltage control oscillator 2201 is the same as that of the voltage control oscillator 2101 of FIG. 21.

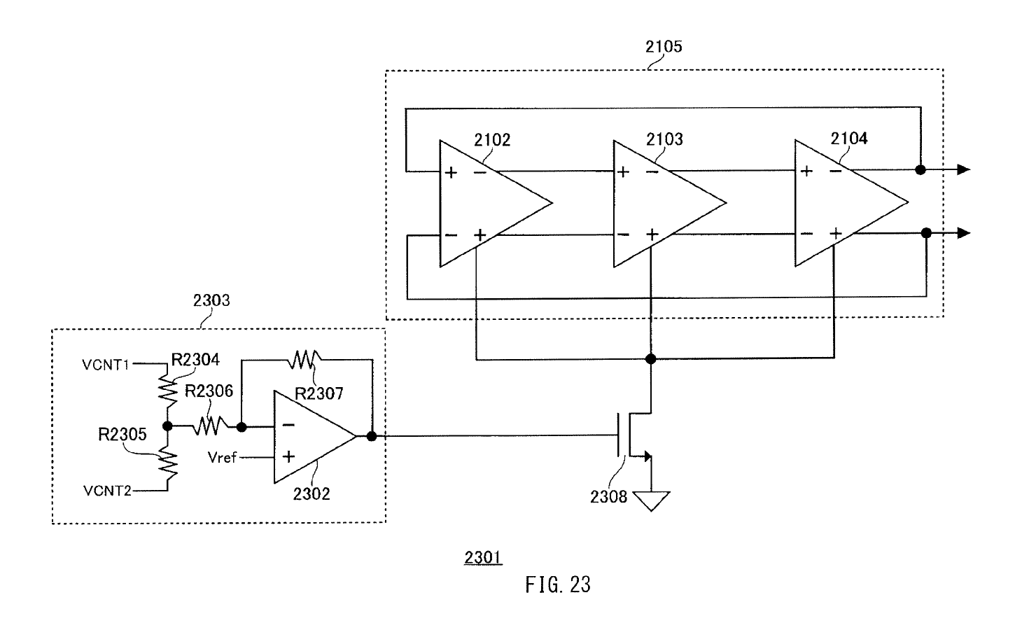

FIG. 23 illustrates a variation of the voltage control oscillator 2101 of FIG. 21, in which the voltage-current conversion circuit 2108 for gain adjustment is replaced with an adder circuit 2303 using an operational amplifier 2302 and NMOSFET 2308. Specifically, the voltage control signals VCNT1 and VCNT2 are added to each other by the adder circuit 2303 with the operational amplifier 2302, so that the NMOSFET 2308 is controlled thereby.

Appropriate setting of a resistance value of each of input resistances R2304 and R2305 allows influence of the shoot-through current, which passes through the first current source 103a (PMOSFET 407) and the second current source 103b (NMOSFET 405), to be eliminated, and allows the clock feed-through phenomenon to be reduced.

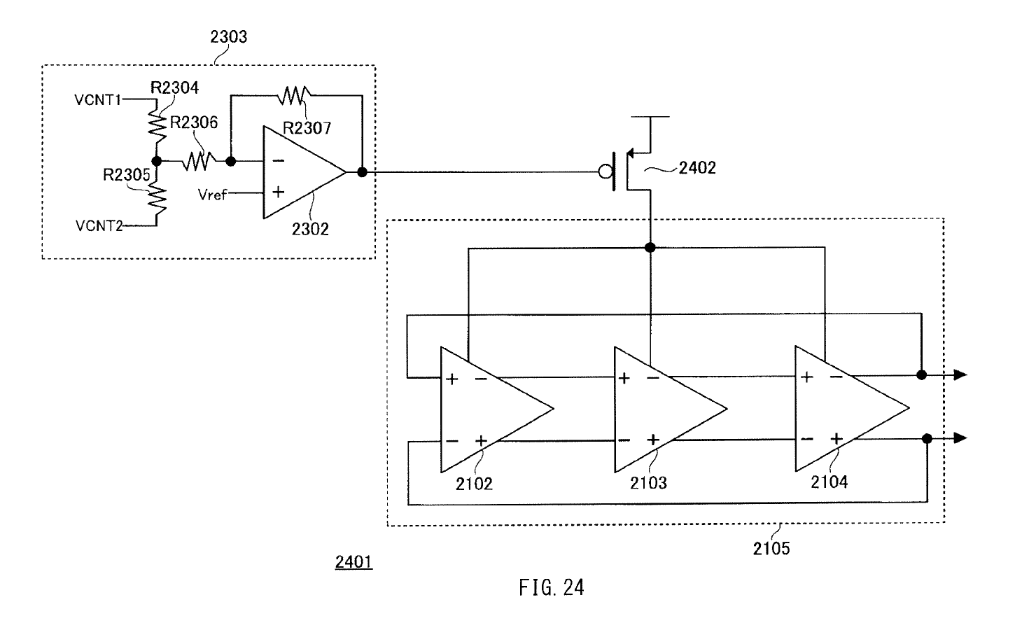

FIG. 24 illustrates a voltage control oscillator 2401 as a variation of the voltage control oscillator 2301 illustrated in FIG. 23, in which ground base is changed to power base. Although MOSFET for gain adjustment is changed to PMOSFET 2402, the operational principle of the voltage control oscillator 2401 is the same as that of the voltage control oscillator 2301 of FIG. 23.

Although the first to fifth embodiments have been described as embodiments of the clock and data recovery circuit hereinbefore, such embodiments may be directly applied to the phase locked loop 101.

The first, second, third, fourth, and fifth embodiments of the present disclosure have disclosed the phase locked loop 101 and the clock and data recovery circuit.

To reduce the stationary phase error that has been an issue in speeding up of the clock and data recovery circuit, an output signal line of the charge pump 103 is divided into lines for the charge current and for the discharge current. Furthermore, the loop filter 105 is also configured to independently function for the charge current and for the discharge current. Furthermore, the voltage control oscillator 108 is also configured to receive the first voltage signal based on the charge current and the second voltage signal based on the discharge current so as to be controlled in oscillation frequency. Thus, the shoot-through current, which passes through the first current source 103a (PMOSFET 407) and the second current source 103b (NMOSFET 405), may not principally occur, and the clock feed-through phenomenon is reduced. As a result, the stationary phase error is reduced.

The phase locked loop 101 and the clock and data recovery circuit according to any of the above-described embodiments of the present disclosure are capable of suppressing mutual interference between the charge current and the discharge current of the charge pump 103, and therefore exhibit the following effects.

(1) AC mismatch between the charge current and the discharge current is reduced.

(2) In the case of the phase locked loop 101, the stationary phase error due to the mutual interference in the charge pump 103 is reduced; hence, clock jitter is reduced.

(3) In the case of the clock and data recovery circuit, the stationary phase error due to the mutual interference in the charge pump 103 and variation in stationary phase error due to variation in input data pattern are suppressed; hence, jitter resistance during reproduction of high-speed data is improved.

(4) Such a reduction in stationary phase error increases a margin in circuit design. Consequently, an allowance for circuit design increases, and a yield in manufacturing of an integrated circuit is promisingly increased. Furthermore, a higher frequency circuit is allowed to be designed at a decreased difficulty. In other words, an information processing unit, a digital television receiver, etc., in which the data transfer rate is increased, is allowed to be achieved.

Although the example embodiments of the present disclosure have been described hereinbefore, the disclosure is not limited thereto, and includes other modifications, alterations, and application examples within the scope without departing from the gist of the disclosure according to the appended claims.

For example, while configurations of units and systems are specifically explained in detail for ease in understanding of the disclosure in the above-described example embodiments, the disclosure is not necessarily limited to such example embodiments having all the described configurations. In addition, part of a configuration of an example embodiment may be replaced with a configuration of another example embodiment. Furthermore, a configuration of an example embodiment may be additionally provided with a configuration of another example embodiment. In addition, part of a configuration of each example embodiment may be additionally provided with a configuration of another example embodiment, omitted, or replaced with a configuration of another example embodiment.

In addition, part or all of the above-described configurations, functions, processing sections, and the like may be achieved by hardware, for example, by design thereof with an integrated circuit. In addition, the above-described configurations, functions, and the like may be achieved by software that allows a processor to interpret a program for achieving each function and to execute the program. Information in a form of a program for achieving each function, a table, a file, or the like may be held in a volatile or nonvolatile storage such as a memory, a hard disk, and a solid state drive (SSD), or in a recording medium such as an IC card and an optical disk.

Moreover, the depicted control lines and information lines are those that are possibly necessary for explanation, namely, all control lines and information lines in a product are not necessarily depicted. Actually, almost all configurations may be considered to be interconnected to one another.

It is possible to achieve at least the following configurations from the above-described example embodiments of the disclosure.
<1> A clock and data recovery circuit, including:

a first current source configured to supply a charge current through a first signal line;

a second current source configured to supply a discharge current through a second signal line provided separately from the first signal line;

a loop filter configured to convert the charge current into a first voltage signal and output the first voltage signal through a third signal line, and to convert the discharge current into a second voltage signal and output the second voltage signal through a fourth signal line;

a voltage control oscillator configured to receive the first voltage signal and the second voltage signal so as to be controlled in frequency; and

a phase detector configured to receive a data signal from outside and receive a clock signal from the voltage control oscillator, and to supply a control signal to each of the first current source and the second current source, and generate a recovery clock signal and a recovery data signal.
<2> The clock and data recovery circuit according to <1>, further including:

a frequency divider configured to divide a frequency of the clock signal;

a phase/frequency detector configured to receive the data signal and a frequency-divided clock signal output by the frequency divider, and to supply a control signal to each of the first current source and the second current source;

a multiplexer configured to selectively output the control signal of the phase detector and the control signal of the phase/frequency detector to the first current source and the second current source; and

a lock detector configured to receive the data signal and the frequency-divided clock signal so as to control the multiplexer.
<3> The clock and data recovery circuit according to <2>, wherein the loop filter includes

a first resistance having a first end to be connected to the first signal line,

a second resistance to be connected between the second signal line and a second end of the first resistance, and

a capacitor to be connected between a connected point of the first resistance and the second resistance and an AC ground node.
<4> The clock and data recovery circuit according to <3>, wherein the voltage control oscillator includes

a first voltage-current converter that converts the first voltage signal into a third current signal,

a second voltage-current converter that converts the second voltage signal into a fourth current signal, and

an oscillator that is controlled in frequency by the third current signal and the fourth current signal.
<5> The clock and data recovery circuit according to <3>, wherein the voltage control oscillator includes

an adder circuit that adds the first voltage signal to the second voltage signal, and

an oscillator that is controlled in frequency by an output signal of the adder circuit.
<6> A phase locked loop, including:

a first current source configured to supply a charge current through a first signal line;

a second current source configured to supply a discharge current through a second signal line provided separately from the first signal line;

a loop filter configured to convert the charge current into a first voltage signal and output the first voltage signal through a third signal line, and to convert the discharge current into a second voltage signal and output the second voltage signal through a fourth signal line;

a voltage control oscillator configured to receive the first voltage signal and the second voltage signal so as to be controlled in frequency; and

a phase/frequency detector configured to receive a reference signal from outside and receive an oscillation signal from the voltage control oscillator, and to supply a control signal to each of the first current source and the second current source.
<7> The phase locked loop according to <6>, wherein the loop filter includes

a first resistance having a first end to be connected to the first signal line,

a second resistance to be connected between the second signal line and a second end of the first resistance, and

a capacitor to be connected between a connected point of the first resistance and the second resistance and an AC ground node.
<8> The phase locked loop according to <7>, wherein the voltage control oscillator includes

a first voltage-current converter that converts the first voltage signal into a third current signal,

a second voltage-current converter that converts the second voltage signal into a fourth current signal, and

an oscillator that is controlled in frequency by the third current signal and the fourth current signal.
<9> The phase locked loop according to <7>, wherein the voltage control oscillator includes

an adder circuit that adds the first voltage signal to the second voltage signal, and

an oscillator that is controlled in frequency by an output signal of the adder circuit.

It should be understood by those skilled in the art that various modifications, combinations, sub-combinations and alterations may occur depending on design requirements and other factors insofar as they are within the scope of the appended claims or the equivalents thereof.

What is claimed is:

1. A clock and data recovery circuit, comprising:
a first current source configured to supply a charge current through a first signal line;
a second current source configured to supply a discharge current through a second signal line provided separately from the first signal line;
a loop filter configured to convert the charge current into a first voltage signal and output the first voltage signal through a third signal line, and to convert the discharge current into a second voltage signal and output the second voltage signal through a fourth signal line;
a voltage control oscillator configured to receive the first voltage signal and the second voltage signal so as to be controlled in frequency; and
a phase detector configured to receive a data signal from outside and receive a clock signal from the voltage control oscillator, and to supply a control signal to each of the first current source and the second current source, and generate a recovery clock signal and a recovery data signal.

2. The clock and data recovery circuit according to claim 1, further comprising:
a frequency divider configured to divide a frequency of the clock signal;
a phase/frequency detector configured to receive the data signal and a frequency-divided clock signal output by the frequency divider, and to supply a control signal to each of the first current source and the second current source;
a multiplexer configured to selectively output the control signal of the phase detector and the control signal of the phase/frequency detector to the first current source and the second current source; and
a lock detector configured to receive the data signal and the frequency-divided clock signal so as to control the multiplexer.

3. The clock and data recovery circuit according to claim 2, wherein the loop filter includes
a first resistance having a first end to be connected to the first signal line,
a second resistance to be connected between the second signal line and a second end of the first resistance, and
a capacitor to be connected between a connected point of the first resistance and the second resistance and an AC ground node.

4. The clock and data recovery circuit according to claim 3, wherein the voltage control oscillator includes
a first voltage-current converter that converts the first voltage signal into a third current signal,
a second voltage-current converter that converts the second voltage signal into a fourth current signal, and
an oscillator that is controlled in frequency by the third current signal and the fourth current signal.

5. The clock and data recovery circuit according to claim 3, wherein the voltage control oscillator includes
an adder circuit that adds the first voltage signal to the second voltage signal, and
an oscillator that is controlled in frequency by an output signal of the adder circuit.

6. A phase locked loop, comprising:
a first current source configured to supply a charge current through a first signal line;
a second current source configured to supply a discharge current through a second signal line provided separately from the first signal line;
a loop filter configured to convert the charge current into a first voltage signal and output the first voltage signal through a third signal line, and to convert the discharge current into a second voltage signal and output the second voltage signal through a fourth signal line;
a voltage control oscillator configured to receive the first voltage signal and the second voltage signal so as to be controlled in frequency; and
a phase/frequency detector configured to receive a reference signal from outside and receive an oscillation signal from the voltage control oscillator, and to supply a control signal to each of the first current source and the second current source.

7. The phase locked loop according to claim 6, wherein the loop filter includes
a first resistance having a first end to be connected to the first signal line,
a second resistance to be connected between the second signal line and a second end of the first resistance, and
a capacitor to be connected between a connected point of the first resistance and the second resistance and an AC ground node.

8. The phase locked loop according to claim 7, wherein the voltage control oscillator includes
a first voltage-current converter that converts the first voltage signal into a third current signal,
a second voltage-current converter that converts the second voltage signal into a fourth current signal, and
an oscillator that is controlled in frequency by the third current signal and the fourth current signal.

9. The phase locked loop according to claim 7, wherein the voltage control oscillator includes
an adder circuit that adds the first voltage signal to the second voltage signal, and
an oscillator that is controlled in frequency by an output signal of the adder circuit.
